(19) United States
(12) Patent Application Publication
(10) Pub. No.: US 2019/0207070 A1
(43) Pub. Date: Jul. 4, 2019

(54) OPTOELECTRONIC COMPONENT AND METHOD OF PRODUCING AN OPTOELECTRONIC COMPONENT

(71) Applicant: OSRAM Opto Semiconductors GmbH, Regensburg (DE)

(72) Inventors: Daniel Richter, Bad Abbach (DE); Daniel Leisen, Regensburg (DE)

(21) Appl. No.: 16/223,931

(22) Filed: Dec. 18, 2018

(30) Foreign Application Priority Data
Dec. 19, 2017 (DE) 10 2017 130 476.2

(51) Int. Cl. H01L 33/62; H01L 33/56; H01L 33/48; H01L 33/00; H01L 33/58

(52) U.S. Cl. CPC H01L 33/62; H01L 33/56; H01L 2933/0091; H01L 33/005; H01L 33/58; H01L 33/483

(57) ABSTRACT

An optoelectronic component includes a housing having a cavity and a bottom, an optoelectronic semiconductor chip arranged on the bottom in the cavity, and a potting body arranged in the cavity, wherein a first region of the potting body has a higher content of filler than a second region of the potting body, and the first region of the potting body adjoins the bottom of the cavity.

### TECHNICAL FIELD

This disclosure relates to an optoelectronic component and to a method of producing an optoelectronic component.

### BACKGROUND

Optoelectronic components in which an optoelectronic semiconductor chip is arranged in a cavity of a housing are known. It is known to fill the cavities in such optoelectronic components with a potting compound, in which the optoelectronic semiconductor chip is embedded.

### SUMMARY

We provide an optoelectronic component including a housing having a cavity and a bottom, an optoelectronic semiconductor chip arranged on the bottom in the cavity, and a potting body arranged in the cavity, wherein a first region of the potting body has a higher content of filler than a second region of the potting body, and the first region of the potting body adjoins the bottom of the cavity.

We also provide a method of producing an optoelectronic component including providing a housing having a cavity and a bottom; arranging an optoelectronic semiconductor chip on the bottom in the cavity; and forming a potting body having a higher content of filler in a first region than in a second region, in the cavity, wherein the first region of the potting body adjoins the bottom of the cavity.

### BRIEF DESCRIPTION OF THE DRAWINGS

FIG. 1 schematically shows a sectional side view of a housing of an optoelectronic component in an unfinished processing state.

FIG. 2 schematically shows the housing after arranging a first potting material in a cavity of the housing.

FIG. 3 schematically shows the housing after arranging a second potting material in the cavity.

FIG. 4 schematically shows the housing after arranging a first potting material in the cavity by an alternative method.

FIG. 5 schematically shows the housing after arranging a second potting material in the cavity.

FIG. 6 schematically shows the housing after arranging a potting material in the cavity by a further alternative method.

FIG. 7 schematically shows the housing after sinking of filler contained in the potting material.

### LIST OF DESIGNATIONS

10 optoelectronic component
20 optoelectronic component
30 optoelectronic component
100 housing
101 upper side
102 underside
110 cavity
120 bottom
130 opening
150 leadframe
160 first leadframe portion
161 chip receiving portion
162 first contact portion
170 second leadframe portion
171 bonding portion
172 second contact portion
200 optoelectronic semiconductor chip
201 upper side
202 underside
210 bonding wire
300 potting body
310 first region
315 first potting material
320 second region
325 second potting material
330 matrix material
340 filler
350 potting material

### DETAILED DESCRIPTION

Our optoelectronic component comprises a housing having a cavity with a bottom. In the cavity, an optoelectronic semiconductor chip is arranged on the bottom. Also arranged in the cavity is a potting body. A first region of the potting body has a higher content of filler than a second region of the potting body. The first region of the potting body adjoins the bottom of the cavity.

The fact that the first region of the potting body of the optoelectronic component has a higher content of filler than the second region of the potting body means that the first region of the potting body can have a coefficient of thermal expansion closer to a coefficient of thermal expansion of the housing than a coefficient of thermal expansion of the second region of the potting body. If the coefficients of thermal expansion of the first region of the potting body and the housing of the optoelectronic component differ to a lesser extent from one another, less severe thermal stresses between the bottom of the housing and the first region of the potting body occur in the optoelectronic component when there are changes in temperature. In this example, with the optoelectronic component there is advantageously a reduced risk of undesired delamination of the potting body from the bottom of the cavity. This is advantageously accompanied by a reduced probability of failure of the optoelectronic component.

Since the second region of the potting body of the optoelectronic component has a lower content of filler than the first region of the potting body, it can be achieved that in the second region of the potting body there is only a small degree of scattering of light emitted by the optoelectronic semiconductor chip of the optoelectronic component at the filler. Lower scattering of light emitted by the optoelectronic semiconductor chip may be advantageously accompanied by lower light absorption. For example, a reduced scattering of light can be achieved by less light emitted by the optoelectronic semiconductor chip of the optoelectronic component being scattered to a wall of the cavity of the housing and absorbed there. As a result, it is possible that with the optoelectronic component there is only a slight losses of brightness due to scattering and absorption.

The potting body may comprise an epoxy. As a result, the potting body can be advantageously produced easily and inexpensively and has a high resistance.

The housing may comprise a polyphthalamide. As a result, the housing can be advantageously produced easily and inexpensively and has a high resistance.

The housing may comprise an embedded leadframe. In this example, the optoelectronic semiconductor chip is arranged on a portion of the leadframe exposed at the bottom of the cavity. The leadframe embedded in the housing advantageously makes electrical contacting of the optoelectronic semiconductor chip of the optoelectronic component possible. The optoelectronic component may, for example, be formed as a surface-mountable component (SMD component).

The filler may comprise SiO₂. The filler may, for example, be arranged in the potting body in the form of particles. SiO₂ advantageously has a low coefficient of thermal expansion. As a result, a filler comprising SiO₂ is suitable for lowering a coefficient of thermal expansion of a potting body filled with the filler. A further advantage of a filler comprising SiO₂ may be that a filler comprising SiO₂ can have a refractive index similar to that of a matrix material of the potting body containing the filler. Furthermore, a filler comprising SiO₂ can be largely transparent to electromagnetic radiation emitted by the optoelectronic semiconductor chip of the optoelectronic component.

The optoelectronic semiconductor chip may be completely embedded in the first region of the potting body. In this example, the optoelectronic component can be advantageously produced particularly easily and inexpensively. Complete embedding of the optoelectronic semiconductor chip in the first region of the potting body can also make it possible to ensure that the bottom of the cavity exclusively adjoins the first region of the potting body, not the second region of the potting body.

The optoelectronic semiconductor chip may be embedded in the first region of the potting body such that an upper side of the optoelectronic semiconductor chip is not arranged in the first region of the potting body. The upper side of the optoelectronic semiconductor chip may be a radiation-emitting surface of the optoelectronic semiconductor chip. Advantageously, electromagnetic radiation emitted by the optoelectronic semiconductor chip then does not get into the first region of the potting body having a higher content of filler. Instead, electromagnetic radiation emitted by the optoelectronic semiconductor chip can go directly into the second region of the potting body, which has a lower content of filler than the first region of the potting body. This can achieve the effect that electromagnetic radiation emitted by the optoelectronic semiconductor chip of the optoelectronic component is only scattered to a slight extent at the filler contained in the potting body.

The first region of the potting body may have embedded carbon black particles. In addition or alternatively, the first region of the potting body may have embedded particles comprising TiO₂. Carbon black particles embedded in the first region of the potting body can achieve the effect that the first region of the potting body has a dark color, whereby a strong contrast in brightness can be obtained in relation to the light-emitting optoelectronic semiconductor chip of the optoelectronic component. Particles comprising TiO₂ embedded in the first region of the potting body can achieve the effect that the first region of the potting body has a light color, whereby the first region of the potting body can have a high reflectivity and a low absorptivity.

The first region of the potting body may have a content of filler of 20 percent by weight to 60 percent by weight. Such a high content of filler advantageously allows a coefficient of thermal expansion of the first region of the potting body to be significantly influenced by the filler.

The second region of the potting body may have a content of filler of 0 percent by weight to 20 percent by weight. Such a low content of filler advantageously allows light emitted by the optoelectronic semiconductor chip of the optoelectronic component to be scattered only to a slight extent in the second region of the potting body.

A coefficient of thermal expansion of the first region of the potting body may differ from a coefficient of thermal expansion of the second region of the potting body. Advantageously, the first region of the potting body can as a result have a coefficient of thermal expansion approximated or assimilated to a coefficient of thermal expansion of the housing of the optoelectronic component. This can achieve the effect that there are only slight thermal stresses between the bottom of the cavity of the housing of the optoelectronic component and the first region of the potting body.

The coefficient of thermal expansion of the first region of the potting body may lie closer to a coefficient of thermal expansion of the housing than the coefficient of thermal expansion of the second region of the potting body. This can advantageously achieve the effect that only slight thermal stresses occur between the bottom of the cavity of the housing of the optoelectronic component and the first region of the potting body under the influence of changes in temperature.

Our method of producing an optoelectronic component comprises steps of providing a housing having a cavity with a bottom, arranging an optoelectronic semiconductor chip on the bottom in the cavity, and forming a potting body having a higher content of filler in a first region than in a second region in the cavity, wherein the first region of the potting body adjoins the bottom of the cavity.

This method makes it possible to produce an optoelectronic component in which the first region of the potting body, adjoining the bottom of the cavity, can have a different coefficient of thermal expansion than the second region of the potting body. As a result, the coefficient of thermal expansion of the first region of the potting body in the optoelectronic component obtainable by the method can be more closely assimilated to a coefficient of thermal expansion of the housing of the optoelectronic component than the coefficient of thermal expansion of the second region of the potting body. This can achieve the effect that in an optoelectronic component produced by the method only slight thermal stresses occur between the bottom of the cavity of the housing and the first region of the potting body under the influence of changes in temperature. As a result, for an optoelectronic component obtainable by the method there may be only a reduced risk of damage or destruction due to thermal influences.

Since the second region of the potting body of an optoelectronic component produced by the method only has a lower content of filler, it is possible that light emitted by the optoelectronic semiconductor chip of the optoelectronic component is only scattered to a slight extent in the second region of the potting body. As a result, scattering and absorption losses in the optoelectronic component obtainable by the method can be low.

Forming the potting body may comprise steps of arranging a first potting material in the cavity to form the first region of the potting body, and arranging a second potting material in the cavity to form the second region of the potting body. This method advantageously makes easy formation of the potting body possible. The use of separate working steps to arrange the first potting material and the second potting material allows the amounts of the first potting material and the second potting material to be precisely fixed in an easy way. This makes it possible also to fix the sizes of the first region of the potting body and the second region of the potting body in an easy way.

Arranging the first potting material may be performed by a first needle dispensing process. Needle dispensing processes are advantageously suitable for rapid and reproducible mass production.

Arranging the first potting material may be performed by jetting. The method advantageously makes it possible to fix the precise location within the cavity of the housing at which the first potting material is arranged and, as a result, the first region of the potting body is formed.

Arranging the second potting material may be performed by a second needle dispensing process. As a result, arranging the second potting material can advantageously also be performed in a reproducible way in the course of mass production.

The first region of the potting body may be cured before arranging the second potting material. As a result, undesired mixing of the first potting material and the second potting material in the cavity of the housing is advantageously prevented.

Forming the potting body comprises steps of arranging a potting material in the cavity and allowing filler contained in the potting material to sink to the bottom of the cavity. The method advantageously makes it possible for the potting body to be formed by just one process step to arrange potting material in the cavity. As a result, the method can be carried out particularly easily, quickly and inexpensively.

The properties, features and advantages described above, and the manner in which they are achieved, will become clearer and more clearly understood in association with the following description of examples explained in greater detail in association with the drawings.

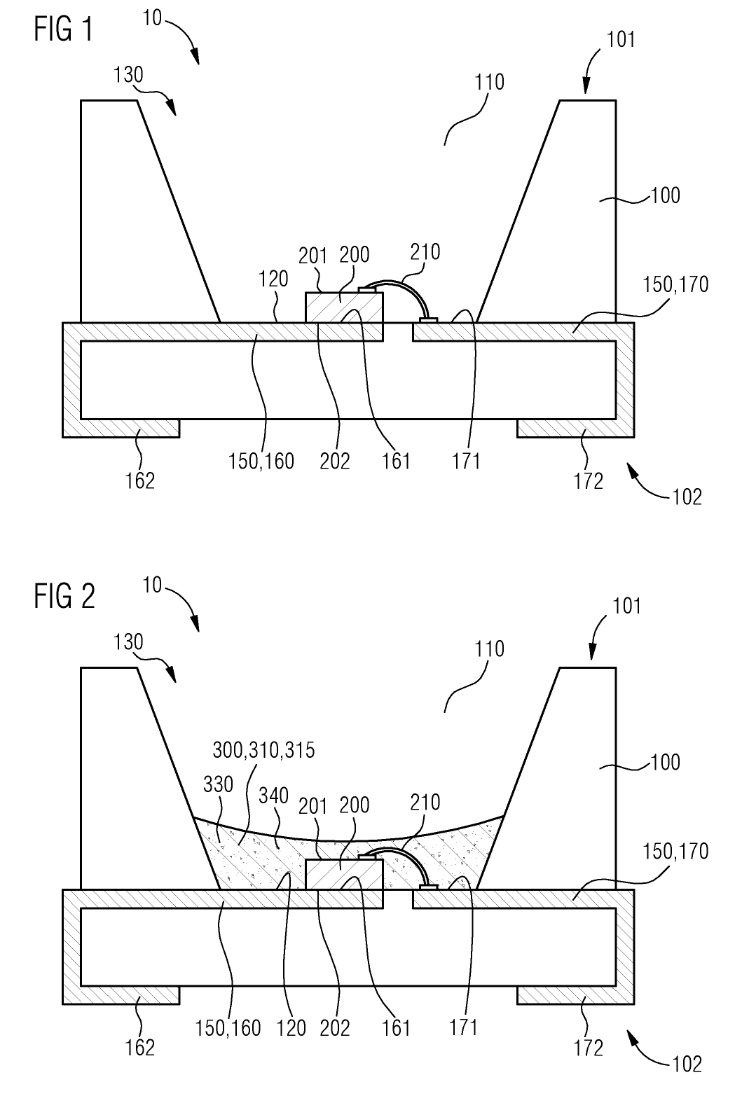

FIG. 1 shows a schematic sectional side view of a housing 100 provided to produce an optoelectronic component 10. An unfinished processing state during production of the optoelectronic component 10 is depicted.

The housing 100 has an upper side 101 and an underside 102 opposite from the upper side 101. The housing 100 has a cavity 110 open toward the upper side 101. The cavity 110 extends from a bottom 120 of the cavity 110 formed at the base of the cavity 110 to an opening 130 of the cavity formed on the upper side 101 of the housing 100. The cavity 110 of the housing 100 in the example depicted extends conically from the bottom 120 to the opening 130. However, this configuration is not obligatory. The cavity 110 can, for example, alternatively be shaped cylindrically.

The housing 100 may have been produced by a molding method, for example, by injection molding or transfer molding. The housing 100 comprises a plastics material. For example, the housing may comprise a polyphthalamide (PPA).

In the example, the housing 100 has an embedded leadframe 150 with a first leadframe portion 160 and a second leadframe portion 170. The leadframe portions 160, 170 of the leadframe 150 may have already been embedded in the material of the housing 100 during production of the housing 100. The leadframe 150 comprises an electrically conducting material, for example, a metal.

The first leadframe portion 160 of the leadframe 150 has a chip receiving portion 161 exposed at the bottom 120 of the cavity 110 of the housing 100. The first leadframe portion 160 extends from the chip receiving portion 161 through the housing 100 to a first contact portion 161 of the first leadframe portion 160 exposed on the underside 102 of the housing 100. The second leadframe portion 170 of the leadframe 150 has a bonding portion 171 exposed at the bottom 120 of the cavity 110. The second leadframe portion 170 extends from the bonding portion 171 through the housing 100 to a second contact portion 172 exposed on the underside 102 of the housing 100.

The chip receiving portion 161 and the bonding portion 171 of the leadframe portions 160, 170 are intended to receive and electrically connect an optoelectronic semiconductor chip, as described below.

The first contact portion 162 and the second contact portion 172 of the leadframe portions 160, 170 are intended for the mounting and electrical contacting of the optoelectronic component 10. In the example, the optoelectronic component 10 may be a surface-mountable SMD component, which may be suitable, for example, for electrical contacting by reflow soldering.

The housing 100 of the optoelectronic component 10 may also be formed differently than how it is depicted by way of example in FIG. 1. For example, instead of the contact portions 162, 172, the leadframe 150 embedded in the housing 100 may have contact pins arranged on the underside 102 of the housing 100 and make mounting and electrical contacting of the optoelectronic component 10 possible by through-hole mounting. It is likewise possible that, instead of the embedded leadframe 150, the housing 100 has embedded vias that establish electrically conducting connections between the bottom 120 of the cavity 110 and the underside 102 of the housing 100.

Arranged in the cavity 110 of the housing 100 is an optoelectronic semiconductor chip 200. The optoelectronic semiconductor chip 200 may be, for example, a light-emitting optoelectronic semiconductor chip in particular, for example, a light-emitting diode chip (LED chip). The optoelectronic semiconductor chip 200 has an upper side 201 and an underside 202 opposite from the upper side 201. The upper side 201 of the optoelectronic semiconductor chip 200 may form a radiation emission area of the optoelectronic semiconductor chip 200 at which electromagnetic radiation, for example, visible light is emitted during operation of the optoelectronic semiconductor chip 200.

The optoelectronic semiconductor chip 200 is arranged on the chip receiving portion 161 of the first leadframe portion 160 exposed at the bottom 120 of the cavity 110 such that the underside 202 of the optoelectronic semiconductor chip 200 faces the chip receiving portion 161. In this example, the optoelectronic semiconductor chip 200 is fastened on the chip receiving portion 161 in an electrically conducting manner such that there is an electrically conducting connection between an electrical contact pad of the optoelectronic semiconductor chip 200 arranged on the underside 202 of the optoelectronic semiconductor chip 200 and the first leadframe portion 160. For example, the optoelectronic semiconductor chip 200 may be fastened on the chip receiving portion 161 of the first leadframe portion 160 by a solder or an electrically conducting adhesive. An electrical contact pad of the optoelectronic semiconductor chip 200 arranged on the upper side 201 of the optoelectronic semiconductor chip 200 connects in an electrically conducting manner to the bonding portion 171 of the second leadframe portion 170 of the housing 100 by a bonding wire 210.

The optoelectronic semiconductor chip 200 can also be fastened and electrically contacted on the bottom 120 of the cavity 110 of the housing 100 in some other way. For example, the two electrical contact pads of the optoelectronic semiconductor chip 200 may be arranged on the upper side 201 of the optoelectronic semiconductor chip 200. In this example, the two electrical contact pads of the optoelectronic semiconductor chip 200 may respectively connect to the first leadframe portion 160 and the second leadframe portion 170 by a bonding wire 210. In this example, the optoelectronic semiconductor chip 200 may be arranged on the chip receiving portion 161 of the first leadframe portion 160 or on another portion of the bottom 120 of the cavity 110. It is also possible that the two electrical contact pads of the optoelectronic semiconductor chip 200 are arranged on the underside 202 of the optoelectronic semiconductor chip 200. In this example, the optoelectronic semiconductor chip 200 may be arranged on the portions 161, 171 of the leadframe portions 160, 170 exposed at the bottom 120 of the cavity 110 such that electrically conducting connections are formed between the electrical contact pads of the optoelectronic semiconductor chip 200 and the first leadframe portion 160 and the second leadframe portion 170, respectively.

FIG. 2 shows a schematic sectional side view of the housing 100 in a processing state following at a time after the situation depicted in FIG. 1.

A first potting material 315 has been arranged in the cavity 110 of the housing 100 to form a first region 310 of a potting body 300. Arranging the first potting material 315 in the cavity 310 may be performed, for example, by a dispensing method, for example, a needle dispensing process.

The first potting material 315 has been introduced into the cavity 110 such that the first region 310 of the potting body 300 formed by the first potting material 315 adjoins the bottom 120 of the cavity 110 of the housing 100. It is expedient to introduce the first potting material 315 into the cavity 110 of the housing 100 such that the bottom 120 of the cavity 110 is completely covered by the first region 310 of the potting body 300 formed by the first potting material 315.

The optoelectronic semiconductor chip 200 has been completely covered by the first potting material 315 arranged in the cavity 110 of the housing 100 so that the optoelectronic semiconductor chip 200 is completely embedded in the first region 310 of the potting body 300 formed by the first potting material 315. This means that the upper side 201 of the optoelectronic semiconductor chip 200 and side flanks of the optoelectronic semiconductor chip 200 extending between the upper side 201 and the underside 202 of the optoelectronic semiconductor chip 200 are covered by the first potting material 315 or the first region 310 of the potting body 300 formed by the first potting material 315.

In the example shown in FIG. 2, the bonding wire 210 is also completely embedded in the first region 310 of the potting body 300 formed by the first potting material 315. However, this is not absolutely necessary.

It is expedient that the covering of the upper side 201 of the optoelectronic semiconductor chip 200 by the first region 310 of the potting body 300 is as thin as possible. It is also possible that the upper side 201 of the optoelectronic semiconductor chip 200 is not covered by the first potting material 315 at all, if the method used to arrange the first potting material 315 in the cavity 110 allows this.

The first potting material 315 comprises a matrix material 330 and a filler 340 embedded in the matrix material 330. The filler 340 may, for example, make up 20 percent by weight to 60 percent by weight of the first potting material 315. The matrix material 330 may, for example, comprise an epoxy. The filler 340 may, for example, comprise SiO₂.

The filler 340 has a coefficient of thermal expansion different from a coefficient of thermal expansion of the matrix material 330. The coefficient of thermal expansion of the filler 340 may, for example, be lower than the coefficient of thermal expansion of the matrix material 330. For example, the filler 340 may have a coefficient of thermal expansion of approximately 5×10⁻⁶/K. The matrix material 330 may, for example, have a coefficient of thermal expansion of approximately 60×10⁻⁶/K. The filler 340 is intended to reduce a coefficient of thermal expansion of the first potting material 315, comprising the matrix material 330 and the filler 340, with respect to the coefficient of thermal expansion of the matrix material 330 without the filler 340. For example, the first potting material 315 may have a coefficient of thermal expansion of approximately 35×10⁻⁶/K.

It is expedient if the coefficient of thermal expansion of the first potting material 315 has a value similar to that of the coefficient of thermal expansion of the material of the bottom 120 of the cavity 110 of the housing 100. For this purpose, the coefficient of thermal expansion of the first potting material 315 may, for example, be adapted to a coefficient of thermal expansion of the material of the housing 100, a coefficient of thermal expansion of the material of the leadframe 150 or an effective coefficient of thermal expansion of the bottom 120 of the cavity 110 of the housing 100 comprising the material of the housing 100 and the exposed portions 161, 171 of the leadframe 150.

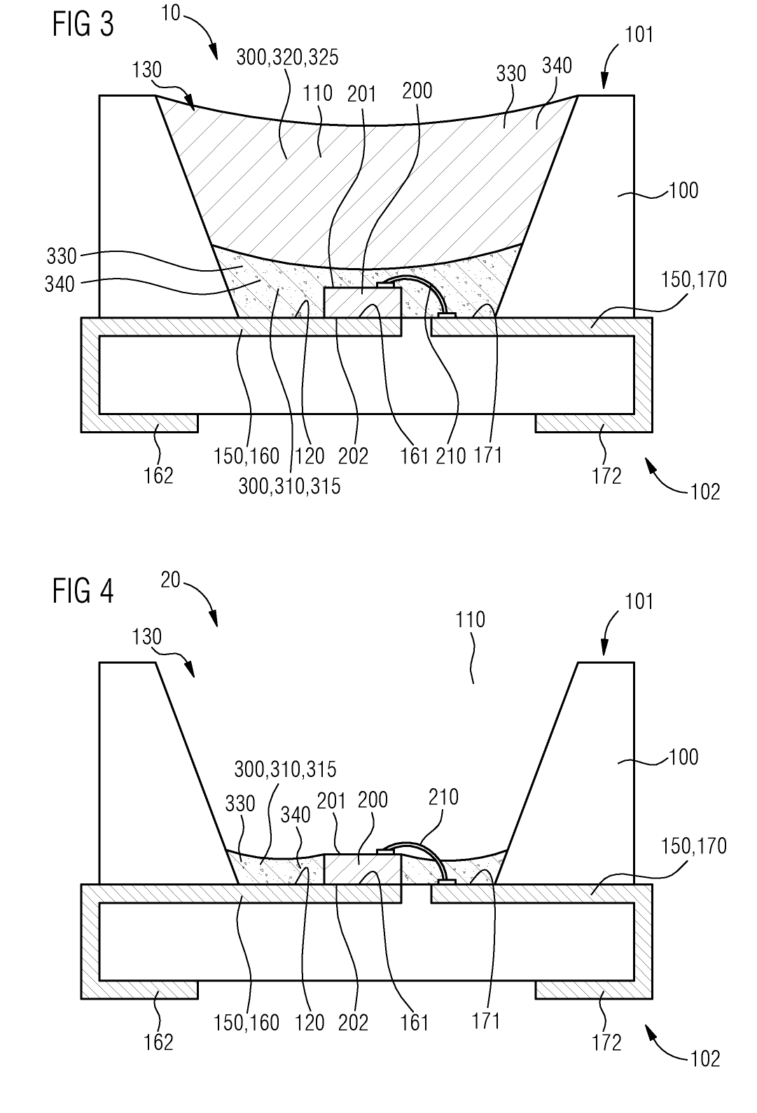

FIG. 3 shows a schematic sectional side view of the housing 100 in a processing state following at a time after the situation depicted in FIG. 2.

Starting from the processing state shown in FIG. 2, a second potting material 325 has been arranged in the cavity 110 of the housing 100 to form a second region 320 of the potting body 300. The second potting material 325 has in this example been arranged over the first potting material 315 and fills the cavity 110 substantially completely. The first region 310 formed by the first potting material 315 and the second region 320 formed by the second material 325 together form the potting body 300 arranged in the cavity 110 of the housing 100.

Arranging the second potting material 325 in the cavity 110 of the housing 100 may have been performed, for example, by a dispensing method, for example, a needle dispensing process. Arranging the second potting material 335 by jetting is also possible.

The second potting material 325 comprises the same matrix material 330 as the first potting material 315. The second potting material 325 may additionally have a content of filler 340. The content of filler 340 is in this example greater in the first potting material 315 than in the second potting material 325. The second potting material 325 may, for example, have a content of filler 340 of 0 percent by weight to 20 percent by weight. This means that the filler 340 can even be omitted completely in the second potting material 325.

Since the first potting material 315 has a different content of filler 340 than the second potting material 325, the coefficient of thermal expansion of the first region 310 of the potting body 300 formed by the first potting material 315, and a coefficient of thermal expansion of the second region 320 of the potting body 300 formed by the second potting material 325, differ from one another. In this example, the coefficient of thermal expansion of the first region 310 of the potting body 300 lies closer to the coefficient of thermal expansion of the bottom 120 of the cavity 110 of the housing 100 than the coefficient of thermal expansion of the second region 320 of the potting body 300.

After arranging the second potting material 325 in the cavity 110, a process step of curing the potting body 300 may be performed. Optionally, a process step of curing the first region 310 of the potting body 300 may even be additionally or alternatively performed already after the arranging of the first potting material 315 in the cavity 110 and before arranging the second potting material 325 in the cavity 110.

In the processing state depicted in FIG. 3, production of the optoelectronic component 10 may have been completed. However, still further processing steps, following after the processing state shown in FIG. 3, may also be performed. The optoelectronic component 10 may, for example, be used in a video wall intended for outdoor use.

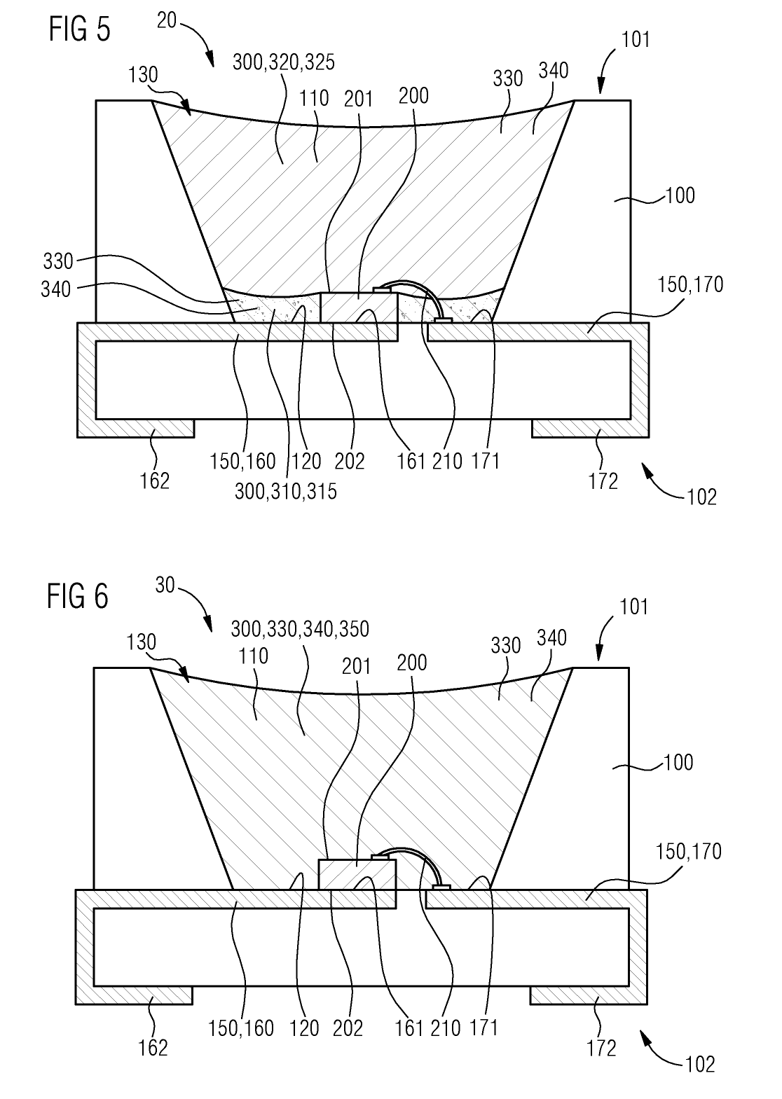

An alternative method of producing an optoelectronic component 20 is explained below on the basis of FIGS. 4 and 5. The method described below of producing the optoelectronic component 20 has great similarities in common with the method of producing the optoelectronic component 10 described above on the basis of FIGS. 1 to 3. Only the differences between the production methods and the differences between the optoelectronic components 10, 20 obtainable by the production methods are described below. Otherwise, the description given above also applies to the method explained below and to the optoelectronic component 20.

The method of producing the optoelectronic component 20 starts from the housing 100 shown in FIG. 1 in the processing state shown in FIG. 1. FIG. 4 shows a schematic sectional side view of the housing 100 in a processing state following at a time after the situation depicted in FIG. 1.

Starting from the processing state shown in FIG. 1, the first potting material 315 has been arranged in the cavity 310 of the housing 100 to form the first region 310 of the potting body 300. In this example, the first potting material 315 has however been arranged such that the upper side 201 of the optoelectronic semiconductor chip 200 has not been covered by the first potting material 315 and, consequently, is not arranged in the first region 310 of the potting body 300 formed by the first potting material 315.

Arranging the first potting material 315 may, for example, have been performed by jetting. Jetting refers to a method in which very small amounts in the form of droplets are fired by a nozzle onto a target location, in this example the bottom 120 of the cavity 110 of the housing 100. The method can make it possible to arrange the first potting material 315 on the bottom 120 of the cavity 110 of the housing 100 in such a specifically directed manner that the upper side 201 of the optoelectronic semiconductor chip 200 arranged on the bottom 120 of the cavity 110 is not covered by the first potting material 315. It is expedient if the portions of the bottom 120 of the cavity 110 of the housing 100 not covered by the optoelectronic semiconductor chip 200 are in this example completely covered by the first potting material 315.

Along with the filler 340, the first potting material 315 arranged in this way in the cavity 110 of the housing 100 may comprise further material embedded in the matrix material 330. For example, the first potting material 315 may have embedded carbon black particles or other color particles to give the first potting material 315 and the first region 310 of the potting body 300 formed by the first potting material 315 a dark, light-absorbing color. Alternatively, the first potting material 315 may have embedded particles comprising TiO₂ to give the first potting material 315 and the first region 310 of the potting body 300 formed by the first potting material 315 a light-reflecting, light color. However, it is not absolutely necessary that the first potting material 315 comprises along with the filler 340 further material embedded in the matrix material 330.

FIG. 5 shows a schematic sectional side view of the housing 100 in a processing state following at a time after the situation depicted in FIG. 4.

Starting from the processing state shown in FIG. 4, the second potting material 325 has been arranged in the cavity 110 of the housing 100 to form the second region 320 of the potting body 300. Arranging the second potting material 325 may have been performed in just the same way as in the method explained above on the basis of FIG. 3 of producing the optoelectronic component 10.

As in the optoelectronic component 10, also in the optoelectronic component 20 the first region 310 of the potting body 300 has a higher content of filler 340 than the second region 320 of the potting body 300.

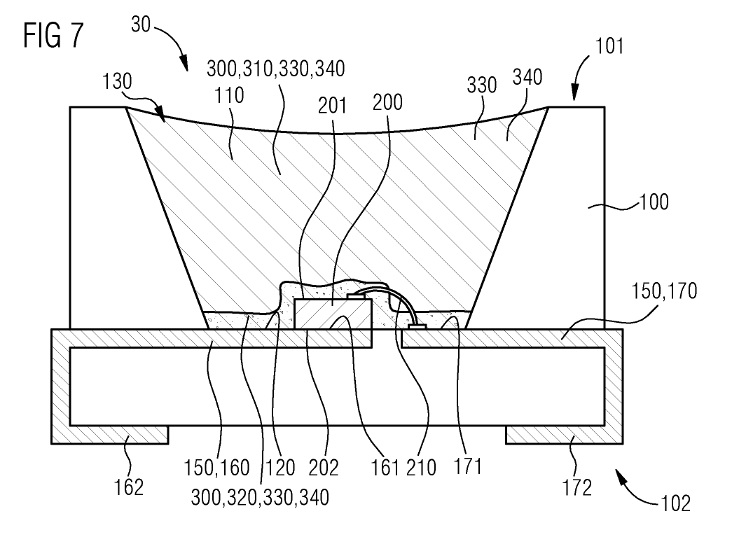

Another alternative method of producing an optoelectronic component 30 is described below on the basis of FIGS. 6 and 7. The method described below of producing the optoelectronic component 30 and the optoelectronic component 30 obtainable by the method described below have great similarities in common with the production method described on the basis of FIGS. 1 to 3 and the optoelectronic component 10 described on the basis of FIGS. 1 to 3. It is only described below in which aspects the production methods and the optoelectronic components 10, 30 obtainable by the production methods differ from one another. Otherwise, the description given above also applies to the method described below and to the optoelectronic component 30.

The method of producing the optoelectronic component 30 starts from the housing 100 shown in FIG. 1 in the processing state shown in FIG. 1. FIG. 6 shows a schematic sectional side view of the housing 100 in a processing state following at a time after the situation depicted in FIG. 1.

Starting from the processing state shown in FIG. 1, a potting material 350 has been arranged in the cavity 110 of the housing 100. The potting material 350 has in this example been arranged in the cavity 110 such that the cavity 110 is filled by the potting material 350 substantially completely. In this example, the potting material 350 adjoins the bottom 120 of the cavity 110 of the housing and covers the optoelectronic semiconductor chip 200 and the bonding wire 210 such that the optoelectronic semiconductor chip 200 and the bonding wire 210 are embedded in the potting material 350. Arranging the potting material 350 in the cavity 110 of the housing 100 may have been performed, for example, by a dispensing method, for example, a needle dispensing process.

The potting material 350 comprises a matrix material 330 and a filler 340 embedded in the matrix material 330. The matrix material 330 and the filler 340 may be formed as the first potting material 315 or the second potting material 325 described above on the basis of FIGS. 2 to 5. In particular, the content of filler 340 in the potting material 350 may lie between the values of the content of filler 340 specified for the first potting material 315 and for the second potting material 325. The filler 340 is initially distributed substantially homogeneously in the potting material 350 after arranging the potting material 350 in the cavity 110 of the housing 100.

FIG. 7 shows a schematic sectional side view of the housing 100 in a processing state following at a time after the situation depicted in FIG. 6.

Starting from the processing state shown in FIG. 6, the filler 340 in the potting material 350 arranged in the cavity 110 of the housing 100 has sunk in the direction of the bottom 120 of the cavity 110. As a result, a first region 310, adjoining the bottom 120 of the cavity 110, and a second region 320, arranged over the first region 310, have formed in the potting body 300 formed by the potting material 350. The first region 310 of the potting body 300 has a higher content of filler 340 than the second region 320 of the potting body 300.

Sinking the filler 340 in the potting material 350 may have been caused by the effect of gravitational force alone. Sinking the filler 340 may however also have been enforced, for example, by a spinning process or other motion of the housing 100.

After sinking the filler 340 in the potting material 350 in the cavity 110 of the housing 100, a further processing step of curing the potting material 350 or the potting body 300 formed by the potting material 350 may be performed.

Our components and methods have been more specifically illustrated and described in detail on the basis of preferred examples. Nevertheless, this disclosure is not restricted to the examples disclosed. Rather, other variations may be derived from them by those skilled in the art without departing from the scope of the appended claims.

1-19. (canceled)

20. An optoelectronic component comprising:
a housing having a cavity and a bottom,
an optoelectronic semiconductor chip arranged on the bottom in the cavity, and
a potting body arranged in the cavity,
wherein a first region of the potting body has a higher content of filler than a second region of the potting body, and
the first region of the potting body adjoins the bottom of the cavity.

21. The optoelectronic component according to claim 20, wherein the potting body comprises an epoxy.

22. The optoelectronic component according to claim 20, wherein the housing comprises a polyphthalamide.

23. The optoelectronic component according to claim 20,
wherein the housing comprises an embedded leadframe, and
the optoelectronic semiconductor chip is arranged on a portion of the leadframe exposed at the bottom of the cavity.

24. The optoelectronic component according to claim 20, wherein the filler comprises SiO₂.

25. The optoelectronic component according to claim 20, wherein the optoelectronic semiconductor chip is completely embedded in the first region of the potting body.

26. The optoelectronic component according to claim 20, wherein the optoelectronic semiconductor chip is embedded in the first region of the potting body such that an upper side of the optoelectronic semiconductor chip is not arranged in the first region of the potting body.

27. The optoelectronic component according to claim 20, wherein the first region of the potting body has embedded carbon black particles or particles comprising TiO₂.

28. The optoelectronic component according to claim 20, wherein the first region of the potting body has a content of filler of 20 percent by weight to 60 percent by weight.

29. The optoelectronic component according to claim 20, wherein the second region of the potting body has a content of filler of 0 percent by weight to 20 percent by weight.

30. The optoelectronic component according to claim 20, wherein a coefficient of thermal expansion of the first region of the potting body differs from a coefficient of thermal expansion of the second region of the potting body.

31. The optoelectronic component according to claim 30, wherein the coefficient of thermal expansion of the first region of the potting body lies closer to a coefficient of thermal expansion of the housing than the coefficient of thermal expansion of the second region of the potting body.

32. A method of producing an optoelectronic component comprising:
providing a housing having a cavity and a bottom;
arranging an optoelectronic semiconductor chip on the bottom in the cavity; and
forming a potting body having a higher content of filler in a first region than in a second region, in the cavity, wherein the first region of the potting body adjoins the bottom of the cavity.

33. The method according to claim 32, wherein forming the potting body comprises:
arranging a first potting material in the cavity to form the first region of the potting body; and
arranging a second potting material in the cavity to form the second region of the potting body.

34. The method according to claim 33, wherein arranging the first potting material is performed by a first needle dispensing process.

35. The method according to claim 33, wherein arranging the first potting material is performed by jetting.

36. The method according to claim 33, wherein arranging the second potting material is performed by a second needle dispensing process.

37. The method according to claim 33, wherein the first region of the potting body is cured before arranging the second potting material.

38. The method according to claim 32, wherein forming the potting body comprises:
arranging a potting material in the cavity; and
allowing filler contained in the potting material to sink to the bottom of the cavity.
